(19) United States
(12) Patent Application Publication
(10) Pub. No.: US 2011/0062503 A1
(43) Pub. Date: Mar. 17, 2011

(54) SEMICONDUCTOR MEMORY DEVICE

(75) Inventors: Atsushi KONNO, Yokohama-shi (JP); Hiroyuki KANAYA, Yokohama-shi (JP)

(73) Assignee: KABUSHIKI KAISHA TOSHIBA, Tokyo (JP)

(21) Appl. No.: 12/720,502

(22) Filed: Mar. 9, 2010

(30) Foreign Application Priority Data
Sep. 11, 2009 (JP) 2009-210753

(51) Int. Cl. H01L 27/108

(52) U.S. Cl. 257/295; 257/296; 257/E27.084

(57) ABSTRACT

A semiconductor memory device includes a plurality of transistors on a semiconductor substrate; a first interlayer dielectric film on the transistors; a plurality of ferroelectric capacitors on the first interlayer dielectric film; a first hydrogen barrier film covering an upper surface and a side surface of each of the ferroelectric capacitors; a second interlayer dielectric film above the ferroelectric capacitors, the second interlayer dielectric film being buried to have a void or hole between two adjacent ferroelectric capacitors out of the ferroelectric capacitors; a cover dielectric film covering the second interlayer dielectric film to close an opening of the void or hole; and a second hydrogen barrier film covering the cover dielectric film.

### CROSS-REFERENCE TO RELATED APPLICATION

This application is based upon and claims the benefit of priority from the prior Japanese Patent Applications No. 2009-210753, filed on Sep. 11, 2009, the entire contents of which are incorporated herein by reference.

### BACKGROUND OF THE INVENTION

1. Field of the Invention

The present invention relates to a semiconductor memory device.

2. Related Art

Generally, a ferroelectric material used for a ferroelectric memory device is reduced by exposure to hydrogen, which deteriorates polarization characteristics of the ferroelectric material. Conventionally, to suppress deterioration in the ferroelectric material, a hydrogen barrier film is formed around ferroelectric capacitors.

The hydrogen barrier film is provided below the ferroelectric capacitors, on side surfaces of the ferroelectric capacitors, and above the ferroelectric capacitors to prevent entry of hydrogen into the ferroelectric capacitors. To suppress entry of hydrogen from above the ferroelectric capacitors, the hydrogen barrier film is also deposited on an interlayer dielectric film coated on the ferroelectric capacitors.

However, voids or holes are sometimes generated in the interlayer dielectric film filled up between two adjacent ferroelectric capacitors. If the hydrogen barrier film is deposited on the interlayer dielectric film, this hydrogen barrier film is damaged or broken resulting from the voids or holes in the interlayer dielectric film. In this case, hydrogen enters into the ferroelectric capacitors from damaged parts of the hydrogen barrier film.

There is proposed an increased thickness of the hydrogen barrier film to suppress damage or breaking of the hydrogen barrier film. However, if the hydrogen barrier film is thick, it disadvantageously takes long time to etch the hydrogen barrier film during formation of contact plugs contacting upper electrodes of the ferroelectric capacitors, respectively.

### SUMMARY OF THE INVENTION

A semiconductor memory device according to an embodiment of the present invention comprises: a plurality of transistors on a semiconductor substrate; a first interlayer dielectric film on the transistors; a plurality of ferroelectric capacitors on the first interlayer dielectric film; a first hydrogen barrier film covering an upper surface and a side surface of each of the ferroelectric capacitors; a second interlayer dielectric film above the ferroelectric capacitors, the second interlayer dielectric film being buried to have a void or hole between two adjacent ferroelectric capacitors out of the ferroelectric capacitors; a cover dielectric film covering the second interlayer dielectric film to close an opening of the void or hole; and a second hydrogen barrier film covering the cover dielectric film.

A semiconductor memory device according to an embodiment of the present invention comprises: a plurality of transistors on a semiconductor substrate; a first interlayer dielectric film on the transistors; a plurality of ferroelectric capacitors on the first interlayer dielectric film; a first hydrogen barrier film covering an upper surface and a side surface of each of the ferroelectric capacitors; a second interlayer dielectric film above the ferroelectric capacitors, the second interlayer dielectric film being buried to have a void or hole between two adjacent ferroelectric capacitors out of the ferroelectric capacitors; and a second hydrogen barrier film buried into the void or cavity, and covered on the second interlayer dielectric film.

A semiconductor memory device according to an embodiment of the present invention comprises: a plurality of transistors on a semiconductor substrate; a first interlayer dielectric film on the transistors; a plurality of ferroelectric capacitors on the first interlayer dielectric film; a first hydrogen barrier film covering an upper surface and a side surface of each of the ferroelectric capacitors; a second interlayer dielectric film above the ferroelectric capacitors, the second interlayer dielectric film being buried between two adjacent ferroelectric capacitors out of the ferroelectric capacitors; and a second hydrogen barrier film covering the second interlayer dielectric film, wherein the side surface of each of the ferroelectric capacitors is formed into a forward tapered shape inclined at an angle equal to or lower than 70 degrees with respect to a bottom or the upper surface of each of the ferroelectric capacitors.

### BRIEF DESCRIPTION OF THE DRAWINGS

FIG. 1 is a cross-sectional view showing a configuration of a ferroelectric memory device according to a first embodiment of the present invention;

FIG. 2 is an enlarged cross-sectional view of the ferroelectric memory device taken along a line 2-2 of FIG. 1;

FIGS. 3 to 7 are cross-sectional views showing a method of manufacturing the ferroelectric memory device according to the first embodiment;

FIG. 8 is a cross-sectional view showing a configuration of a ferroelectric memory device according to a second embodiment of the present invention;

FIG. 9 is a cross-sectional view showing a configuration of a ferroelectric memory device according to a third embodiment of the present invention;

FIG. 10 is a cross-sectional view showing a configuration of a ferroelectric memory device according to a fourth embodiment of the present invention; and

FIG. 11 is a graph showing the relationship between tapered angles θ of each ferroelectric capacitor C and occurrence rates of the holes V.

### DETAILED DESCRIPTION OF THE INVENTION

Embodiments of the present invention will be explained below in detail with reference to the accompanying drawings. Note that the invention is not limited thereto.

### First Embodiment

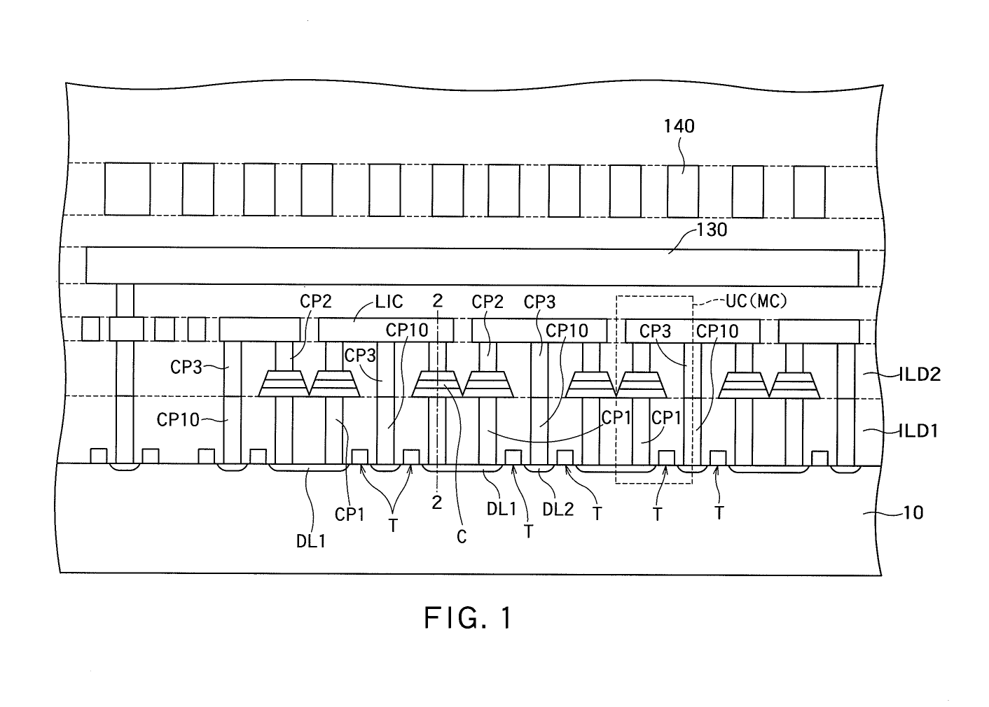

FIG. 1 is a cross-sectional view showing a configuration of a ferroelectric memory device according to a first embodiment of the present invention. FIG. 1 shows a memory which consists of series connected memory cells each having a transistor having a source terminal and a drain terminal and a ferroelectric capacitor inbetween said two terminals, hereafter named “Series connected TC unit type ferroelectric RAM”. FIG. 1 is a cross-sectional view of the ferroelectric memory device along a direction in which the unit cells UC are connected in series (an extension direction of bit lines 130). The first embodiment is not limited to the Series connected TC unit type ferroelectric RAM but applicable to an arbitrary memory device including ferroelectric capacitors.

The ferroelectric memory device according to the first embodiment includes a silicon substrate 10, cell transistors T provided on the silicon substrate 10, a first interlayer dielectric film ILD1 formed on the cell transistors T, and ferroelectric capacitors C provided above the first interlayer dielectric film ILD1. Although not shown in FIG. 1, a plurality of ferroelectric capacitors C is two-dimensionally arranged above the silicon substrate 10 in a matrix.

A gate of each cell transistor T functions as a word line WL. The bit lines 130 are orthogonal to word lines WL. Each interconnect 140 is connected to each word line WL and functions to reduce resistance of the word line WL.

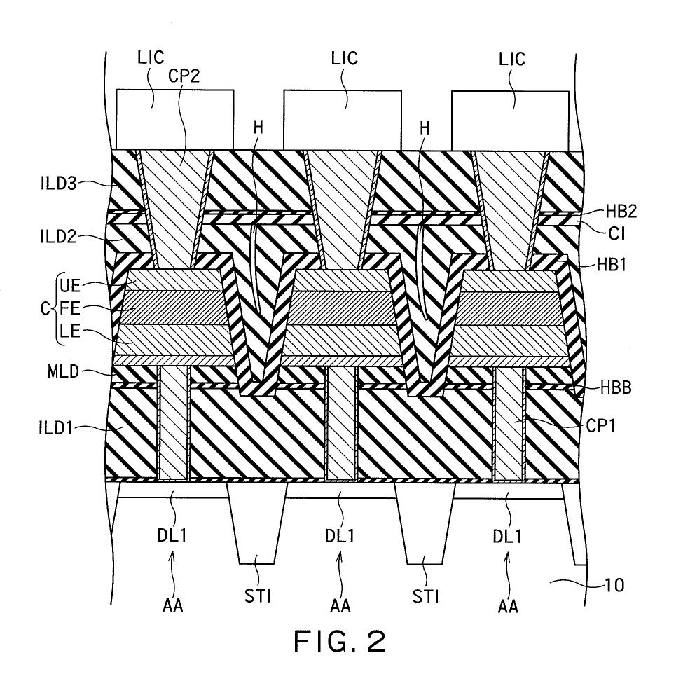

FIG. 2 is an enlarged cross-sectional view of the ferroelectric memory device taken along a line 2-2 of FIG. 1. FIG. 2 shows cross sections of three ferroelectric capacitors C. Element isolation STIs (Shallow Trench Isolations) are formed in the silicon substrate 10. An active area AA is formed between two adjacent STIs. Each cell transistor T is formed on the active area AA. Because FIG. 2 is the cross-sectional view along an extension direction of the word lines WL, the cell transistors T appear only on a diffusion layer DL1 in FIG. 2.

The first interlayer dielectric film ILD1 is deposited on the silicon substrate 10. The first interlayer dielectric film ILD1 is a silicon oxide film made of, for example, BPSG (Boron Phosphorous Silicate Glass) or TEOS (Tetra Ethoxy Silane). A bottom hydrogen barrier film HBB is provided on the first interlayer dielectric film ILD1. The bottom hydrogen barrier film HBB is made of, for example, Al₂O₃ or SiN. The bottom hydrogen barrier film HBB is provided to block hydrogen that is to enter from a bottom of each ferroelectric capacitor C. An intermediate dielectric film MLD is provided on the bottom hydrogen barrier film HBB. The intermediate dielectric film MLD is, for example, a silicon oxide film.

First contact plugs CP1 and CP10 are provided to penetrate through the intermediate dielectric film MLD, the bottom hydrogen barrier film HBB, and the first interlayer dielectric film ILD1. The first contact plugs CP1 and CP10 are made of, for example, tungsten or doped polysilicon. Because the first contact plugs CP1 and CP10 are formed simultaneously, these contact plugs CP1 and CP10 are both referred to as “first contact plugs”. It is to be noted, however, that the first contact plug CP1 is connected to the diffusion layer DL1 and that the first contact plug CP10 is connected to a diffusion layer DL2. Because FIG. 2 is the cross-sectional view along the extension direction of the word lines WL, no contact plugs CP10 appear in FIG. 2.

Each ferroelectric capacitor C is provided on one first contact plug CP1. A lower electrode LE of the ferroelectric capacitor C is electrically connected to one of the diffusion layers DL1 of one cell transistor T via the corresponding first contact plug CP1.

Each ferroelectric capacitor C includes the lower electrode LE, a ferroelectric film FE, and an upper electrode UE. The lower electrode LE is a monolayer film made of, for example, Ti, TiN, TiAlN, Pt, Ir, IrO₂, SRO, Ru or RuO₂, or a multilayer film made of a combination thereof. The ferroelectric film FE is made of, for example, PZT (Pb(ZrₓTi₍ᵢ₋ₓ₎)O₃), SBT (SrₓBi_{y}Ta_{z}Oₐ) or BLT (BiₓLa_{y}O_{z}), where x, y, z, and “a” are positive numbers. The upper electrode UE is a monolayer film made of, for example, Pt, Ir, IrO₂, SRO, Ru or RuO₂, or a multilayer film made of a combination thereof.

A first hydrogen barrier film HB1 is coated on an upper surface and a side surface of each ferroelectric capacitor C. The first hydrogen barrier film HB1 is made of, for example, Al₂O₃ or SiN.

A second interlayer dielectric film ILD2 is provided on the upper surface and the side surface of each ferroelectric capacitor C via the first hydrogen barrier film HB1. The second interlayer dielectric film ILD2 is a silicon oxide film made of, for example, BPSG or TEOS. An upper surface of the second interlayer dielectric film ILD2 is flattened. The second interlayer dielectric film ILD2 is buried to include a void or a hole between the two adjacent ferroelectric capacitors C. This void or hole remains as a cavity H by coating a cover dielectric film CI on an opening of the void or hole to close the opening.

The cover dielectric film CI is a silicon oxide film made of, for example, BPSG or TEOS. The cover dielectric film CI can be formed of either a different material from that of the second interlayer dielectric film ILD2 or the same material (SiO₂) as that of the second interlayer dielectric film ILD2.

A second hydrogen barrier film HB2 is formed to be coated on the cover dielectric film CI. The second hydrogen barrier film HB2 is made of, for example, Al₂O₃ or SiN. The cover dielectric film CI can be made thicker than the second hydrogen barrier film HB2. This is because the material of the cover dielectric film CI is higher than that of the second hydrogen barrier film HB2 in etching rate (during, for example, RIE (Reactive Ion Etching)). Accordingly, even if the cover dielectric film CI is formed to be thick, the thick cover dielectric film CI does not require so long etching time. By forming the cover dielectric film CI to be thicker than the second hydrogen barrier film HB2, the cover dielectric film CI can be coated on the opening of each void or hole. As a result, the cavity H remains between the two adjacent ferroelectric capacitors C.

However, because the cover dielectric film CI is coated on the opening of each void or hole, the second hydrogen barrier film HB2 can be coated on an entire upper surface of the cover dielectric film CI without damaging or breaking the second hydrogen barrier film HB2. It is thereby possible to prevent invasion of hydrogen from above the ferroelectric capacitors C.

The cover dielectric film CI and the second hydrogen barrier film HB2 are deposited on the flattened second interlayer dielectric film ILD2. This can thereby improve coatability of the second hydrogen barrier film HB2 and the second hydrogen barrier film HB2 can exhibit a sufficient hydrogen barrier effect.

A third interlayer dielectric film ILD3 is provided on the second hydrogen barrier film HB2. The third interlayer dielectric film ILD3 can be made of the same material as that of the second interlayer dielectric film ILD2. Second contact plugs CP2 are formed to penetrate through the third interlayer dielectric film ILD3, the second hydrogen barrier film HB2, the cover dielectric film CI, the second interlayer dielectric film ILD2, and the first hydrogen barrier film HB1. The second contact plugs CP2 are made of a material selected from among a group consisting of, for example, W, Al, TiN, Cu, Ti, Ta and TaN.

Third contact plugs CP3 are formed to penetrate through the third interlayer dielectric film ILD3, the second hydrogen barrier film HB2, the cover dielectric film CI, the second interlayer dielectric film ILD2, and the first hydrogen barrier film HB1, and to be electrically connected to the contact plugs CP10, respectively. The third contact plugs CP3 are made of, for example, tungsten or doped polysilicon. Because FIG. 2 is the cross-sectional view along the extension direction of the word lines WL, the third contact plugs CP3 do not appear in FIG. 2.

A local interconnect LIC is formed on the second and third contact plugs CP2 and CP3. The local interconnect LIC is made of, for example, a material selected from among a group consisting of, for example, W, Al, TiN, Cu, Ti, Ta and TaN. The local interconnect LIC is electrically connected to the upper electrode UE of one ferroelectric capacitor C via the corresponding second contact plug CP2.

In this way, in the first embodiment, the cover dielectric film CI is provided below the second hydrogen barrier film HB2. The second hydrogen barrier film HB2 can be thereby coated above the ferroelectric capacitors C without being damaged or broken resulting from the opening of each void or hole. As a consequence, it is possible to ensure protecting the ferroelectric capacitors C from entry of hydrogen according to the first embodiment.

In the first embodiment, it suffices that the second hydrogen barrier film HB2 is thick (for example, about 10 nanometers (nm)) enough to block hydrogen and it is unnecessary to make the second hydrogen barrier film HB2 equal to or thicker than about 10 nm. Even if the second hydrogen barrier film HB2 is quite thin in this way, the second hydrogen barrier film HB2 can sufficiently exhibit the hydrogen barrier effect. By providing the thin second hydrogen barrier film HB2, etching can be easily performed during formation of the second contact plugs CP2.

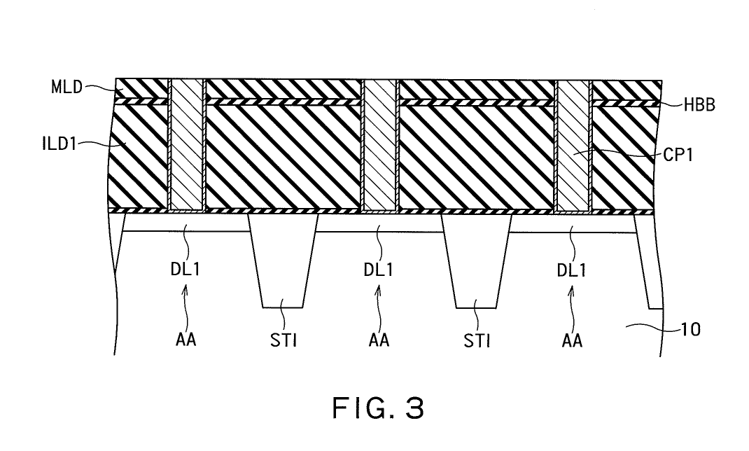

FIGS. 3 to 6 are cross-sectional views showing a method of manufacturing the ferroelectric memory device according to the first embodiment.

The STIs are formed on the silicon substrate 10. The active areas AA are thereby decided. Each of the cell transistors T is formed on each active area AA. The cell transistor T can be formed by a similar manufacturing method to a method of manufacturing an ordinary MISFET (Metal Insulation Semiconductor Field Effect Transistor). The method of manufacturing the cell transistor T is, therefore, not described herein in detail.

The first interlayer dielectric film ILD1 is then deposited on the silicon substrate 10 and the cell transistors T. The upper surface of the first interlayer dielectric film ILD1 is flattened by CMP (Chemical Mechanical Polishing). Next, the bottom hydrogen barrier film HBB and the interlayer dielectric film MLD are deposited on the first interlayer dielectric film ILD1.

The intermediate dielectric film MLD, the bottom hydrogen barrier film HBB, and the first interlayer dielectric film ILD1 located on the diffusion layers DL1 and DL2 are then selectively removed using lithography and RIE. Contact holes are thereby formed on the diffusion layers DL1 and DL2. A conductive material (tungsten or doped silicon) is buried into the contact holes and this conductive material is flattened by the CMP. As a result, the contact plugs CP1 are formed as shown in FIG. 3

The materials of the lower electrode LE, the ferroelectric film FE, and the upper electrode UE are then deposited on the intermediate dielectric film MLD and the first contact plugs CP1. A conductive hydrogen barrier film 50 can be provided between each lower electrode LE and each first contact plug CP1. The hydrogen barrier film 50 is a monolayer film made of, for example, titanium nitride (T₃N₄ or the like), titanium aluminum nitride (TiₓAl_{y}N_{z} or the like), tungsten nitride (WₓN_{y} or the like) or titanium (Ti), or a multilayer film made of a combination thereof.

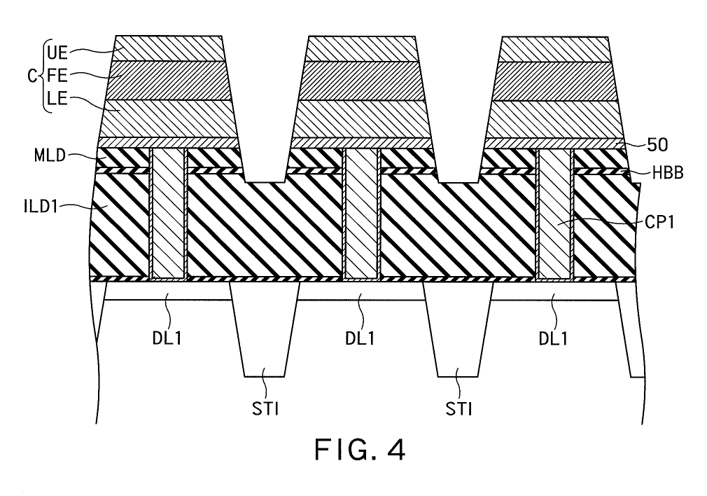

A mask material (not shown) is then deposited on the material of the upper electrode UE. The mask material is, for example, a silicon oxide film, Al₂O₃ or TiAlN. The mask material is then patterned using the lithography and RIE. Subsequently, using the patterned mask material as a mask, the upper electrode UE, the ferroelectric film FE, and the lower electrode LE are continuously processed. As a result, the ferroelectric capacitors C are formed as shown in FIG. 4. At this time, the layers or films between the adjacent ferroelectric capacitors C are overetched to etch also the bottom hydrogen barrier film HBB.

The first hydrogen barrier HB1 is then deposited to be coated on the upper and side surfaces of each ferroelectric capacitor C. The first hydrogen barrier film HB1 contacts with the bottom hydrogen barrier film HBB and thereby surrounds the ferroelectric capacitors C.

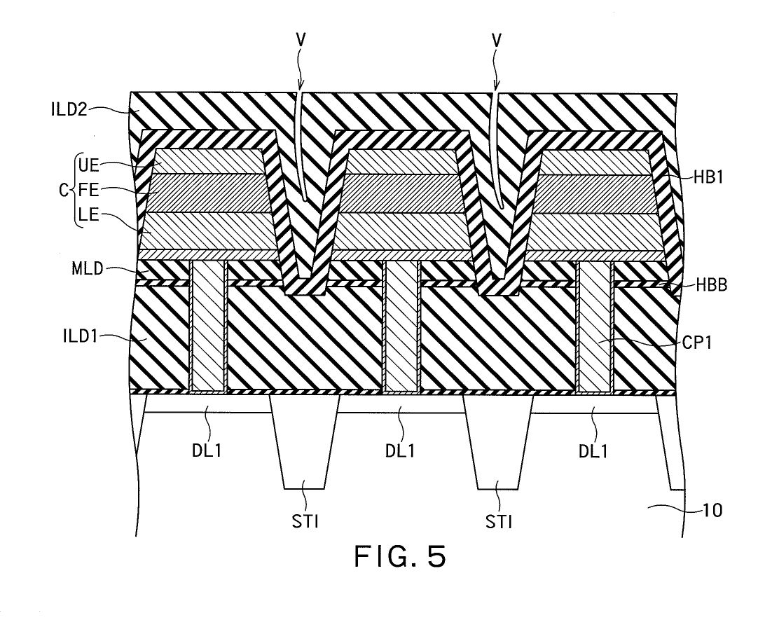

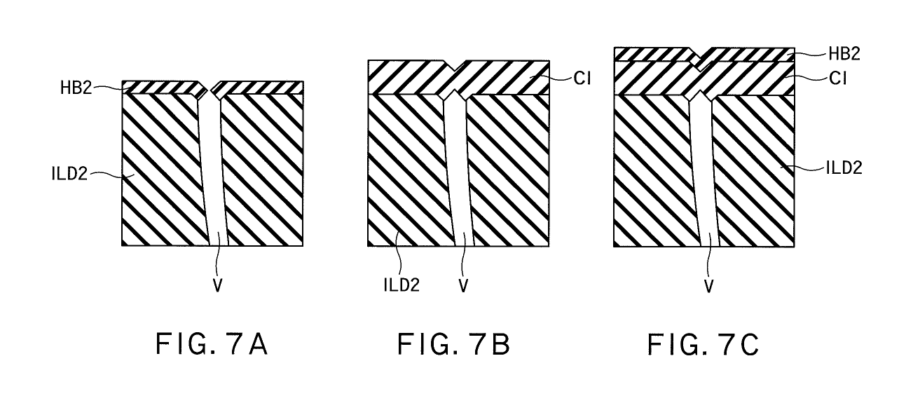

The second interlayer dielectric film ILD2 is then deposited on the first hydrogen barrier film HB1 using PECVD (Plasma-enhanced Chemical Vapor Deposition), sputtering or the like, and the upper surface of the second interlayer dielectric film ILD2 is flattened. The second interlayer dielectric film ILD2 is deposited not only on the upper surface of each ferroelectric capacitor C but also filled up between the adjacent ferroelectric capacitors C. An aspect ratio between the adjacent ferroelectric capacitors C has become quite high with recent downscaling of the ferroelectric memory devices. Therefore, as shown in FIG. 5, the second interlayer dielectric film ILD2 filled up therebetween often includes voids or holes V. In this case, as shown in a comparative example shown in FIG. 7A, if the thin second hydrogen barrier film HB2 is directly deposited on the second interlayer dielectric film ILD2, the second hydrogen barrier film HB2 is damaged or broken.

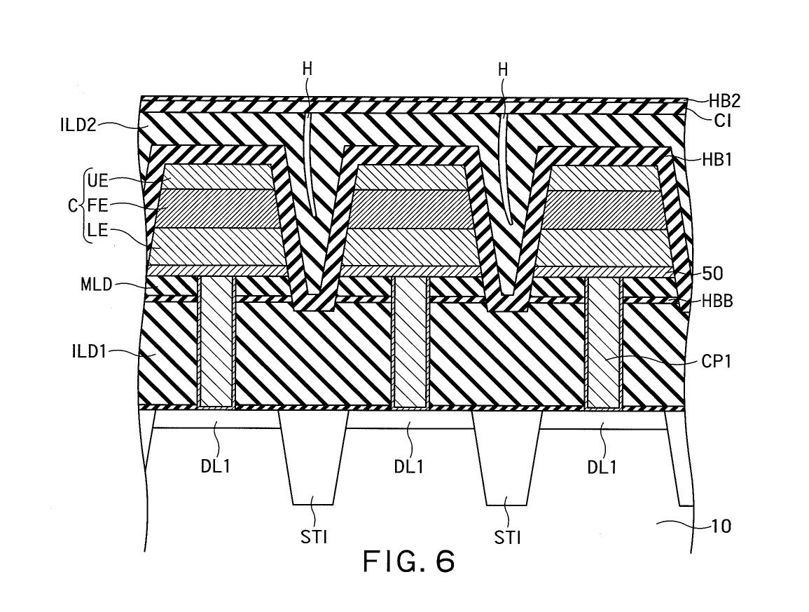

In the first embodiment, the cover dielectric film CI is deposited on the second interlayer dielectric film ILD2 using the PECVD, sputtering or the like as shown in FIG. 6, and the second hydrogen barrier film HB2 is deposited on the cover dielectric film CI. FIGS. 7B and 7C are enlarged cross-sectional views showing how the cover dielectric film CI and the second hydrogen barrier film HB2 are deposited. As shown in FIG. 7B, the thicker cover dielectric film CI than the second hydrogen barrier film HB2 is deposited on the second interlayer dielectric film ILD2, whereby the cover dielectric film CI can close the opening of each void or hole V without being damaged or broken. As shown in FIG. 7C, the second hydrogen barrier film HB2 is deposited on the cover dielectric film CI, whereby the second hydrogen barrier film HB2 can be coated on the cover dielectric film CI without being damaged or broken.

By causing the cover dielectric film CI to close the opening of each void or hole V, it is possible to form the stable second hydrogen barrier film HB2 without being broken in the void or hole V even if the second hydrogen barrier film HB2 is as thin as about 10 nm. The cover dielectric film CI is a silicon oxide film or the like normally used as an interlayer dielectric film. As the second hydrogen barrier film HB2, an alumina film, a silicon nitride film or the like lower than the interlayer dielectric film (silicon oxide film) in hydrogen permeability is used. Such a film is normally lower than the silicon oxide film in etching rate. Therefore, the second hydrogen barrier film HB2 can be formed to be thin, and therefore it is possible to facilitate forming the second contact plugs CP2.

Next, the third interlayer dielectric film ILD3 is deposited on the second hydrogen barrier film HB2. Contact holes reaching the upper electrodes UE are formed. A conductive material is buried into the contact holes using MOCVD (Metalorganic CVD), sputtering, plating or sputtering-reflow. This conductive material is then flattened by the CMP. As a result, the second contact plugs CP2 are formed. Likewise, the contact plugs CP3 to be connected to the contact plugs CP10, respectively are formed.

The local interconnect LIC is formed on the second contact plugs CP2 and the third contact plugs CP3, thereby obtaining the structure shown in FIG. 2.

According to the first embodiment, even if the void or hole V is formed in the second interlayer dielectric film ILD2 between the two adjacent ferroelectric capacitors C, the second hydrogen barrier film HB2 can be coated on the second interlayer dielectric film ILD2 without being damaged or broken.

### Second Embodiment

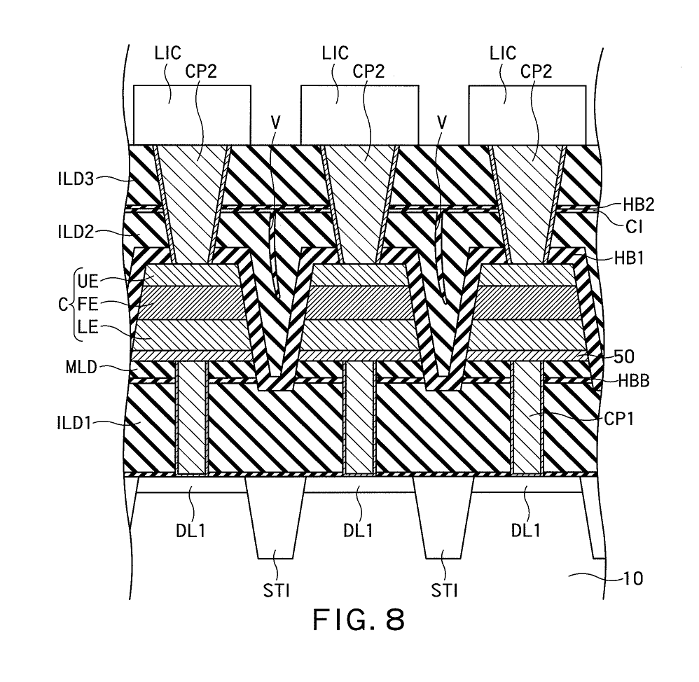

FIG. 8 is a cross-sectional view showing a configuration of a ferroelectric memory device according to a second embodiment of the present invention. In the second embodiment, the cover dielectric film CI is coated on the second interlayer dielectric film ILD2 and is buried into each void or hole V. The other configurations of the ferroelectric memory device according to the second embodiment can be similar to corresponding configurations of the ferroelectric memory device according to the first embodiment. According to the second embodiment, the second hydrogen barrier film HB2 is prevented from being damaged or broken by burying each void or hole V with the cover dielectric film CI although there are no cavities H after manufacturing of the ferroelectric memory device. Therefore, the second embodiment can provide identical effects as those of the first embodiment.

In the second embodiment, because there are no cavities H, it is possible to prevent foreign matters such as water, hydrogen, gas containing hydrogen atoms as constituent atoms or the like from being accumulated in the cavities H, and to suppress deterioration in ferroelectric capacitors C accordingly.

As a method of manufacturing the ferroelectric memory device according to the second embodiment, the material of the cover dielectric film CI is deposited by ALD (Atomic Layer Deposition) or coating after executing the steps described with reference to FIGS. 3 to 5. When SiO₂ is deposited using the ALD, the cover dielectric film CI can be deposited even in an interior of each narrow void or hole V differently from deposition using ordinary CVD. On the other hand, the manufacturing cost is increased when the ALD is used. Therefore, a coating oxide film such as an SOG film can be formed on the second interlayer dielectric film ILD2 as the cover dielectric film CI. For example, PSZ (poly silazane) can be coated on the second interlayer dielectric film ILD2 to form the cover dielectric film CI. Thereafter, the second hydrogen barrier film HB2 is deposited on the cover dielectric film CI similarly to the first embodiment.

Subsequent steps of manufacturing the ferroelectric memory device according to the second embodiment can be similar to corresponding steps in the first embodiment. In this way, the ferroelectric memory device according to the second embodiment is completed.

### Third Embodiment

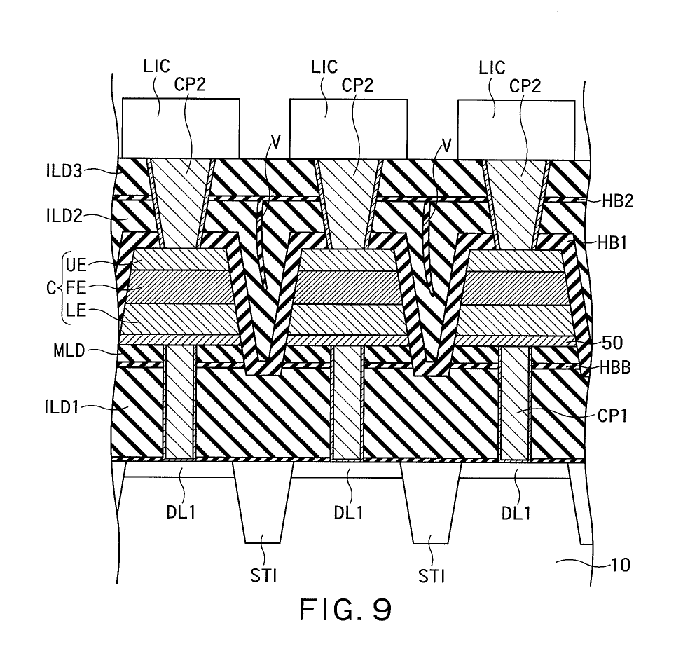

FIG. 9 is a cross-sectional view showing a configuration of a ferroelectric memory device according to a third embodiment of the present invention. In the third embodiment, the second hydrogen barrier film HB2 is coated on the second interlayer dielectric film ILD2 and buried into each void or hole V. In the third embodiment, the cover dielectric film CI is not formed. The other configurations of the ferroelectric memory device according to the third embodiment can be similar to corresponding configurations of the ferroelectric memory device according to the first embodiment. According to the third embodiment, the second hydrogen barrier film HB2 is prevented from being damaged or broken by burying each void or hole V with the second hydrogen barrier film HB2 although there are no cavities H after manufacturing of the ferroelectric memory device. Therefore, the third embodiment can provide identical effects as those of the first embodiment.

Because there are no cavities H in the third embodiment, similarly to the second embodiment, it is possible to prevent foreign matters such as water, hydrogen, gas containing hydrogen atoms as constituent atoms or the like from being remained in the cavities H, and to suppress deterioration in ferroelectric capacitors C accordingly.

As a method of manufacturing the ferroelectric memory device according to the third embodiment, a material of the second hydrogen barrier film HB2 is deposited by ALD after executing the steps described with reference to FIGS. 3 to 5. For example, Al₂O₃ or SiN is deposited using the ALD as the material of the second hydrogen barrier film HB2. In this case, the second hydrogen barrier film HB2 can be deposited even in an interior of each narrow void or hole V differently from deposition using ordinary CVD. On the other hand, the manufacturing cost is increased when the ALD is used. However, the number of manufacturing steps decreases because there is no need to deposit the cover dielectric film CI. Therefore, it is possible to suppress an increase in the manufacturing cost or reduce the manufacturing cost accordingly.

Moreover, an aspect ratio of the contact hole formed on each upper electrode UE can be reduced because the cover dielectric film CI is not deposited. This can reduce contact resistance between a local interconnect LIC and the upper electrode UE and can suppress contact failure.

### Fourth Embodiment

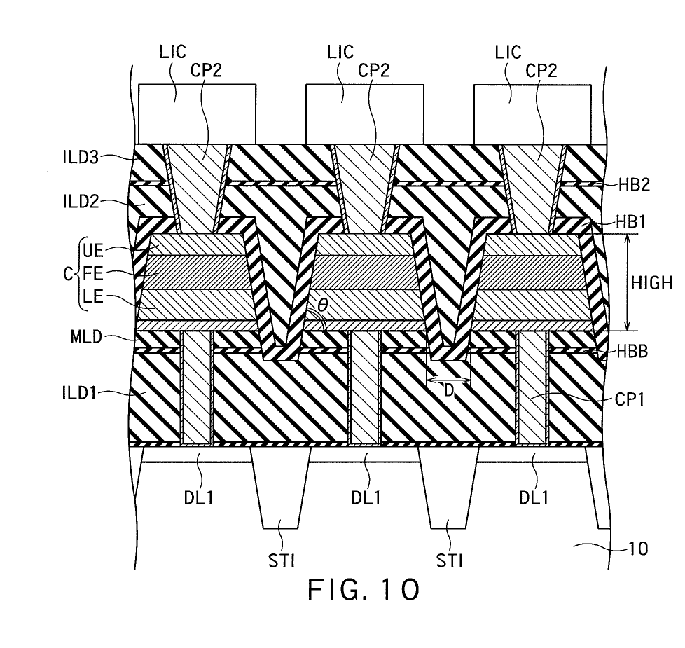

FIG. 10 is a cross-sectional view showing a configuration of a ferroelectric memory device according to a fourth embodiment of the present invention. In the fourth embodiment, a side surface of each ferroelectric capacitor C is formed into a forward tapered shape inclined at an angle θ equal to or lower than 70 degrees with respect to a bottom or an upper surface of the ferroelectric capacitor C. In this case, a height HIGH of the ferroelectric capacitor C is about 300 nm to about 400 nm. A distance D between two adjacent ferroelectric capacitors C is about 60 nm to about 100 nm. A thickness of the first hydrogen barrier film HB1 is about 50 nm to about 100 nm. In this case, no voids or holes V are generated in the second interlayer dielectric film ILD2.

Other configurations of the ferroelectric memory device according to the fourth embodiment can be similar to corresponding configurations of the ferroelectric memory device according to the third embodiment.

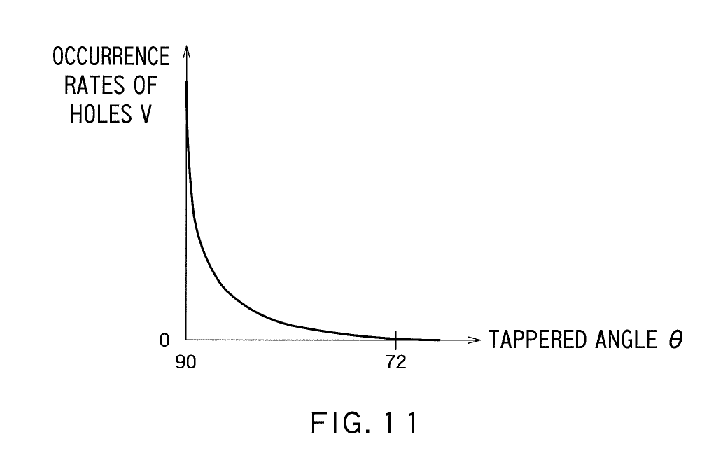

FIG. 11 is a graph showing the relationship between tapered angles θ of each ferroelectric capacitor C and occurrence rates of the holes V. As shown in the graph of FIG. 11, when the tapered angle θ is equal to or lower than 70 degrees under the conditions above mentioned, the occurrence rate of the holes V is almost zero.

The fourth embodiment is applicable only when the tapered angle θ of each ferroelectric capacitor C is allowed to be reduced. However, the fourth embodiment can provide identical effects as those of the first embodiment without greatly altering a conventional manufacturing method.

1. A semiconductor memory device comprising:
a plurality of transistors on a semiconductor substrate;
a first interlayer dielectric film on the transistors;
a plurality of ferroelectric capacitors on the first interlayer dielectric film;
a first hydrogen barrier film on an upper surface and a side surface of each ferroelectric capacitor;
a second interlayer dielectric film above the ferroelectric capacitors and inbetween two adjacent ferroelectric capacitors out of the ferroelectric capacitors with either a gap or a hole;
a cover dielectric film on the second interlayer dielectric film configured to close an opening of the gap or hole; and
a second hydrogen barrier film on the cover dielectric film.

2. The device of claim 1, wherein a cavity of the gap or hole remains between the two adjacent ferroelectric capacitors.

3. The device of claim 1, wherein the cover dielectric film is in the gap or hole and configured to cover the second interlayer dielectric film.

4. The device of claim 1, wherein the cover dielectric film comprises a material of the second interlayer dielectric film.

5. The device of claim 2, wherein the cover dielectric film comprises a material of the second interlayer dielectric film.

6. The device of claim 3, wherein the cover dielectric film comprises a material of the second interlayer dielectric film.

7. The device of claim 1, wherein the cover dielectric film is thicker than the second hydrogen barrier film.

8. The device of claim 2, wherein the cover dielectric film is thicker than the second hydrogen barrier film.

9. The device of claim 3, wherein the cover dielectric film is thicker than the second hydrogen barrier film.

10. The device of claim 1, wherein a first etching rate for etching the cover dielectric film is higher than a second etching rate for etching the second hydrogen barrier film.

11. The device of claim 2, wherein a first etching rate for etching the cover dielectric film is higher than a second etching rate for etching the second hydrogen barrier film.

12. The device of claim 3, wherein a first etching rate for etching the cover dielectric film is higher than a second etching rate for etching the second hydrogen barrier film.

13. The device of claim 1, wherein an upper surface of the second interlayer dielectric film is flat.

14. A semiconductor memory device comprising:
a plurality of transistors on a semiconductor substrate;
a first interlayer dielectric film on the transistors;
a plurality of ferroelectric capacitors on the first interlayer dielectric film;
a first hydrogen barrier film on an upper surface and a side surface of each ferroelectric capacitor;
a second interlayer dielectric film above the ferroelectric capacitors and inbetween two adjacent ferroelectric capacitors out of the ferroelectric capacitors with either a gap or hole; and
a second hydrogen barrier film in the gap or hole, and on the second interlayer dielectric film.

15. The device of claim 14, wherein an upper surface of the second interlayer dielectric film is flat.

16. A semiconductor memory device comprising:
a plurality of transistors on a semiconductor substrate;
a first interlayer dielectric film on the transistors;
a plurality of ferroelectric capacitors on the first interlayer dielectric film;
a first hydrogen barrier film on an upper surface and a side surface of each ferroelectric capacitor;
a second interlayer dielectric film above the ferroelectric capacitors and inbetween two adjacent ferroelectric capacitors out of the ferroelectric capacitors; and
a second hydrogen barrier film on the second interlayer dielectric film
wherein the side surface of each of the ferroelectric capacitors is in a forward tapered shape with an angle equal to or smaller than 70 degrees with respect to a bottom or the upper surface of each ferroelectric capacitor.
